(19) United States
(12) Patent Application Publication
(10) Pub. No.: US 2003/0222308 A1
(43) Pub. Date: Dec. 4, 2003

(54) SOI MOSFET with compact body-tied-source structure

(75) Inventors: Ke-Wei Su, Tainan (TW); Jaw-Kang Her, Taipei (TW); Fu-Liang Yang, Hsin-chu City (TW); Yi-Ling Chan, Junan Jen (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 10/159,771

(22) Filed: May 30, 2002

(51) Int. Cl. H01L 27/01

(52) U.S. Cl. 257/347

(57) ABSTRACT

A method for forming an SOI (Silicon-on-Insulator) semiconductor device and a SOI semiconductor device formed thereof, wherein the SOI semiconductor device comprises a source, a drain, and a gate formed upon a substrate. At least one P+ body contact region is generally located adjacent the source and away from a channel of the SOI semiconductor device. At least one poly tee may be connected to the gate, such that the poly tee passes through the P+ body contact region. The P+ body contact region and the source can be connected together on a surface of a silicon film utilizing a silicide, thereby forming the SOI semiconductor device.

### TECHNICAL FIELD

The present invention relates to a semiconductor devices and fabrication methods thereof. This invention also relates to a silicon-on insulator(SOI) device and a method for fabricating the same. In addition, the present invention relates to SOI MOS devices and body-tied-to-source structures thereof.

### BACKGROUND OF THE INVENTION

Silicon-on-insulator (SOI) technology has become an increasingly important technique utilized in the fabrication and production of semiconductor devices. SOI technology deals with the formation of transistors in a relatively thin monocrystalline semiconductor layer, which overlays an insulating layer. The insulating layer is typically formed on an underlying substrate, which may be silicon. In other words, the active devices are formed in a thin semiconductor on insulator layer rather than in the bulk semiconductor of the device. Currently, silicon is most often used for this monocrystalline semiconductor layer in which devices are formed. However, it will be understood by those skilled in the art that other monocrystalline layers such as germanium or gallium arsenide may be used. Accordingly, any subsequent reference to silicon will be understood to include any semiconductor material.

High performance and high-density integrated circuits are achievable by using the SOI technology because of the reduction of parasitic elements present in integrated circuits formed in bulk semiconductors. For example, for a MOS transistor formed in bulk, parasitic capacitance is present at the junction between the source/drain regions and the underlying substrate, and the possibility of breakdown of the junction between source/drain regions and the substrate regions also exist. A further example of parasitic elements is present for CMOS technology in bulk, where parasitic bipolar transistors formed by n-channel and p-channel transistors in adjacent wells can give rise to latch-up problems. Since SOI structures significantly alleviate parasitic elements, and increase the junction breakdown tolerance of the structure, the SOI technology is well suited for high performance and high-density integrated circuits.

SOI technology allows for the mapping of standard advanced technologies into a SOI technology without significant modifications. SOI process techniques include epitaxial lateral overgrowth (ELO), lateral solid-phase epitaxy (LSPE) and full isolation by porous oxidized silicon (FIPOS). SOI networks can be constructed using the semiconductor process of techniques of separation by implanted oxygen (SIMOX) and wafer-bonding and etch-back (SIBOND) because they achieve low defect density, thin film control, good minority carrier lifetimes and good channel mobility characteristics.

SOI technology exhibits its advantages for higher speed, lower power consumption and better radiation immunity due to the enhanced isolation of buried oxide layers. Because the body of a typical SOI MOS, however, is generally isolated from the silicon substrate, the body is usually kept floating, and this may result in serious problems for current-sensitive circuit applications. FIG. 1 illustrates a prior art schematic diagram of an SOI semiconductor device 10 having a body 18, a source 12, a drain 14 and a gate 16. Various body contacts located at the edges of the device channel 20 have been utilized, as illustrated in FIG. 1. As can be seen in FIG. 1, however, another extra body terminal and increasingly complex routing configurations are required. Additionally, the pick-up capability of body contacts degrades substantially when the channel length L is shrunk or the width W of the channel 20 is widened.

A variety of solutions have been proposed to address the problems associated with the SOI semiconductor device illustrated in FIG. 1. FIG. 2 depicts a prior art schematic diagram of an SOI transistor 22 having a body node to source node connection. Prior art SOI transistor 22 is disclosed in U.S. Pat. No. 4,965,213 to Blake, which describes a method of forming a silicon-on-insulator MOS transistor. U.S. Pat. No. 4,965,213 generally discloses a silicon-on-insulator MOS transistor, which includes an implanted region on the source side of the gate electrode for making contact to the body node. A contact region of the same conductivity type as the body node is formed within the source region in a self-aligned fashion relative to the gate electrode. Ohmic contact is then made between the abutting source region and the contact region.

Thus, as indicated in FIG. 2, extra P+ implants 28 and 29 in the source region (i.e., source 24) are utilized to connect to the internal body under gate 28. The body contact and the source region are linked together via silicide on the surface of the silicon film. Although redundant routing for body contacts are avoided in the prior art configuration of FIG. 2, serious limitations exist due to the presence of the P+ implants 28 and 29. The channel length should not be too short so that the P+ implant will not overlap the drain region (i.e., drain 26). Implanting P+ near the active channel region 27 can also cause some influence on the performance of the resulting SOI transistor 22. The configuration depicted in FIG. 2 also does not improve the problems associated with wide channel devices.

Other body-tied-source configurations have also been proposed. FIG. 3 illustrates a prior art SOI device 30 having a body node contact. SOI device 30 is described U.S. Pat. No. 5,804,858 to Hsu el al., which discloses a method of forming a SOI device having a body node contact. In U.S. Pat. No. 5,804,858, active areas are isolated from one another within a silicon-on-insulator layer. Adjacent active areas are doped with dopants of opposite poloarities to form an n-channel active area and a p-channel active area. Gate electrodes are formed over each active area. The area directly underlying the gate electrode and extending downward to the insulator layer comprises the body node. Thus, as indicated in FIG. 3, a gate 36 is formed in contact with a channel 38, which sits adjacent n-channel active area 39 and p-channel active area 37. The basic limitation of channel length still exists in the device illustrated in FIG. 3.

Other attempts have been made at developing structures so that the unnecessary limitation of channel length may be prevented. As depicted in FIG. 4, however, a prior art SOI device 40 still suffers from the influence of a P+ implant on a channel. In FIG. 4, a source 42 is illustrated, along with a drain and a gate 46. N-channel regions 41 and 43 are also depicted in FIG. 4. The solution illustrated, which is disclosed in U.S. Pat. No. 6,177,708 to Kuang et al. is also ineffective for wide-channel devices. The L-shaped poly gate 48 on the OD region may even cause additional process or reliability troubles. Thus, the influence of P+ implant 45 on the channel region still exists.

Based on the foregoing, the present inventors have thus concluded that a need exists for a silicon-on-insulator (SOI) device which does not contain the channel length and/or width limitations associated with the above referenced prior art SOI devices. Additionally, the present inventors have concluded that this need can be solved with an improved SOI device and associated fabrication methods, which are disclosed herein, which additionally leads to improvements in process and reliability for such a device.

### BRIEF SUMMARY OF THE INVENTION

The following summary of the invention is provided to facilitate an understanding of some of the innovative features unique to the present invention, and is not intended to be a full description. A full appreciation of the various aspects of the invention can be gained by taking the entire specification, claims, drawings, and abstract as a whole.

It is therefore one aspect of the present invention to provide an improved semiconductor fabrication method and devices thereof.

It is another aspect of the present invention to provide an improved SOI semiconductor device.

It is an additional aspect of the present invention to provide an improved method for fabricating an SOI semiconductor device.

The above and other aspects of the present invention can thus be achieved as is now described. A method for forming a SOI (Silicon-on-Insulator) semiconductor device and a SOI semiconductor device formed thereof are described herein, wherein the SOI semiconductor device comprises a source, a drain, and a gate formed upon a substrate. At least one P+ body contact region is generally located adjacent the source and away from a channel of the SOI semiconductor device. At least one poly tee may be connected to the gate, such that the poly tee passes through the P+ body contact region. The P+ body contact region and the source can be connected together on a surface of a silicon film utilizing a silicide, thereby forming the SOI semiconductor device. Additionally, at least one gate contact to the poly tee may be formed. A layer of silicide may be established upon the gate, wherein the gate comprises a gate formed from polysilicon. The poly tee generally comprises a polysilicon structure. Additionally, a plurality of poly tees may be added to the SOI semiconductor device to compensate for wide channel SOI semiconductor devices.

The P+ region is generally located beside the source so that the total occupied area can be reduced. The P+ region is also located away from the channel so that the P+ implant has less influence on the device behavior. Additionally, the P+ region is not located anymore close to the channel so that the prior art limitations of channel length to avoid overlaps between P+ and drain regions do not exist. This is a significant improvement over the prior art devices discussed herein.

Additional poly tees may be extended from the poly gate so that the p-body is formed under the tees and the neutral body of channel can be connected to the P+ region via this newly created p-body. Poly tees passing through the P+ region are also configured so that the newly created p-body is ensured to reach the P+ region. Poly tees passing through the P+ region can also provide the facility to add gate contacts at the side of the source.

Gate contacts on the poly tees are also available according to the device structure of the present invention so that additional gate contacts can be added to reduce the RC distribution effect along the poly gate and to alleviate the load of the tunneling gate leakage current, especially in the case of ultra wide and short channel devices with thin front oxide layers thereof. Finally, more than one tee can be added so that the pick-up capability of body contact can be improved even for ultra wide channel devices.

### BRIEF DESCRIPTION OF THE DRAWINGS

The accompanying figures, in which like reference numerals refer to identical or functionally-similar elements throughout the separate views and which are incorporated in and form part of the specification, further illustrate the present invention and, together with the detailed description of the invention, serve to explain the principles of the present invention.

FIG. 1 illustrates a prior art schematic diagram of an SOI semiconductor device having a body, a source, a drain and a gate;

FIG. 2 depicts a prior art schematic diagram of an SOI transistor having a body node to source node connection;

FIG. 3 illustrates a prior art SOI device having a body node contact;

FIG. 4 depicts a prior art SOI device in which the influence of a P+ implant on a channel is prevalent;

FIG. 5 illustrates a body-tied-to-source SOI MOS device, in accordance with a preferred embodiment of the present invention;

FIG. 6 depicts a body-tied-to-source SOI MOS device, in accordance with an alternative embodiment of the present invention;

FIG. 7 illustrates a cross section AA of a body-tied-to-source SOI MOS device, in accordance with preferred or alternative embodiments of the present invention;

FIG. 8 depicts a cross section BB of a body-tied-to-source SOI MOS device, in accordance with preferred or alternative embodiments of the present invention; and

FIG. 9 illustrates a cross section CC of a body-tied-to-source SOI MOS device, in accordance with preferred or alternative embodiments of the present invention.

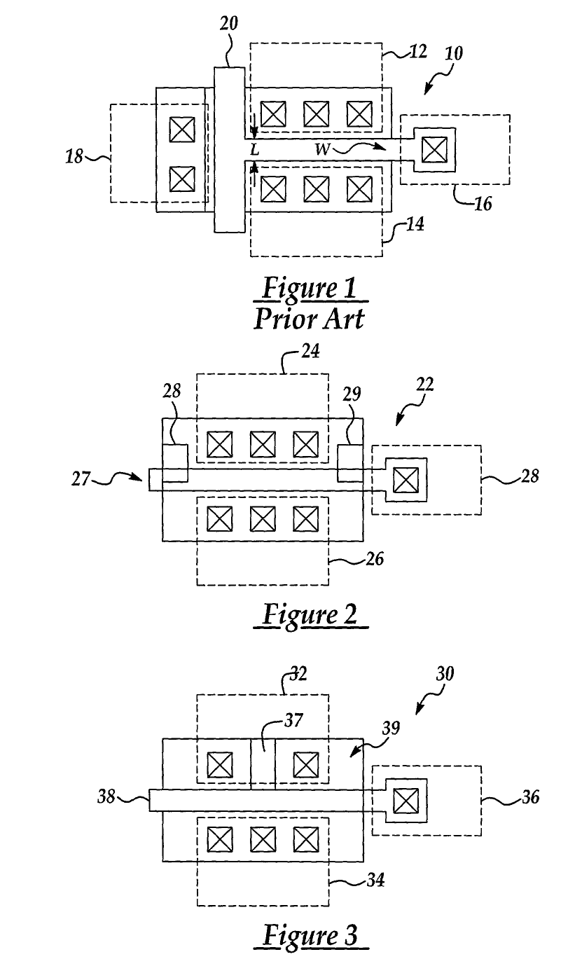

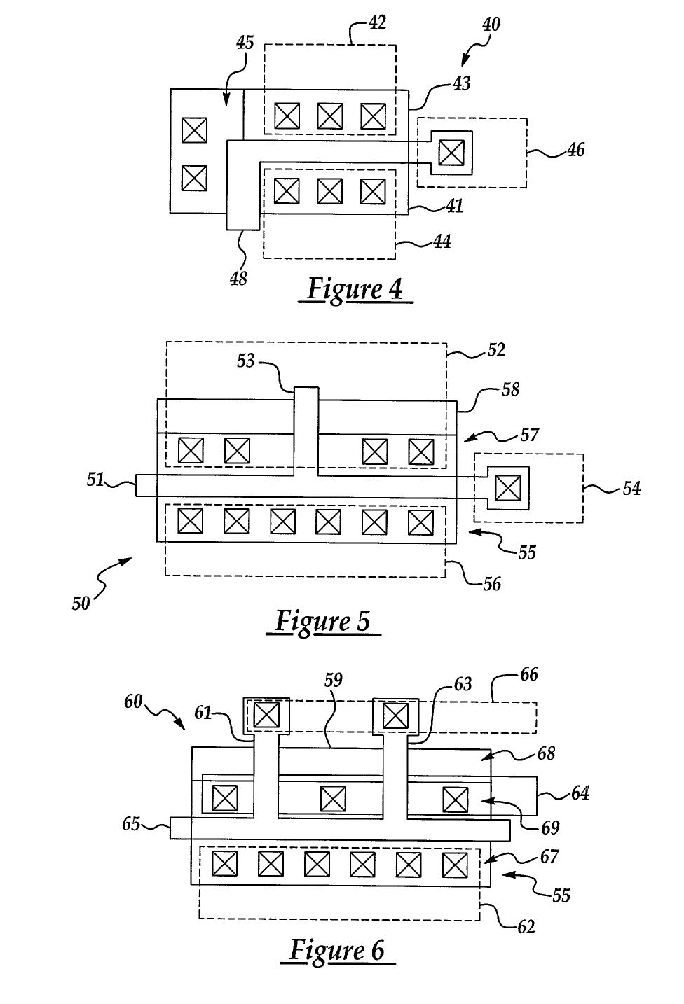

### DETAILED DESCRIPTION OF THE INVENTION

The particular values and configurations discussed in these non-limiting examples can be varied and are cited merely to illustrate embodiments of the present invention and are not intended to limit the scope of the invention.

FIG. 5 illustrates a body-tied-to-source SOI MOS device 50, in accordance with a preferred embodiment of the present invention. SOI MOS device 50 may be formed in a relatively thin monocrystalline semiconductor layer, which overlays an insulating layer. Such an insulating layer is typically formed on an underlying substrate, which may be silicon. In other words, the SOI MOS device 50 can be formed in a thin semiconductor on insulator layer rather than in the bulk semiconductor of the device.

As illustrated in FIG. 5, a P+ body contact region 58 is located adjacent to source 52. P+ body contact region 58 is also located away from channel region 51. Additional extended poly tees (i.e., tee 51) are added to the poly gate 54. The extended poly tee 53 passes through P+ body contact region 58. P+ body contact region 58 and N+ source 52 are connected together by the silicide on the surface of a silicon film. N+ regions 55 and 57 are thus generally illustrated in FIG. 5, along with a drain 56 and cross sectional lines AA′, BB′, and CC′.

Gate contacts to the poly tees are also available. Poly gate 54 can be implanted with different types of dopants and can be shortened by the silicide located on the top of the poly (i.e., polysilicon). Additional poly tees can be added for wider channel devices if necessary. The source regions generally are separated by the poly tees but can be connected together via metal 1 or P+ to body P+ path. In FIG. 5 only poly tee configuration is illustrated. Multiple poly tees are illustrated in FIG. 6.

FIG. 6 depicts a body-tied-to-source SOI MOS device 60, in accordance with an alternative embodiment of the present invention. The device 60 illustrated in FIG. 6 generally comprises a drain 62, a source 59 and two poly tees 61 and 63, which can be joined together through channel 65. Additionally, as indicated in FIG. 6, a P+ body contact region 68 can be located adjacent to source 59. P+ body contact region 68 is also generally located away from the channel region (i.e., channel 65). Poly tees 61 and 63 can be added to a poly gate.

The extended poly tees 61 and 63 thus can pass through P+ body contact region 68. P+ body contact region 68 and N+ source 59 can be connected together by the silicide on the surface of a silicon film. Gate contacts to the poly tees are also generally available. The poly gate can be implanted with different types of dopants and can be shortened by the silicide located on the top of the poly (i.e., polysilicon).

Additional poly tees can be added for wider channel devices if necessary. The source regions generally are separated by the poly tees but can connected together via metal 1 (i.e., metal 66) or a P+ to body P+ path. Note that although an NMOS structure is illustrated in FIGS. 5 to 9 herein, the principles claimed and described herein can apply equally to PMOS structures.

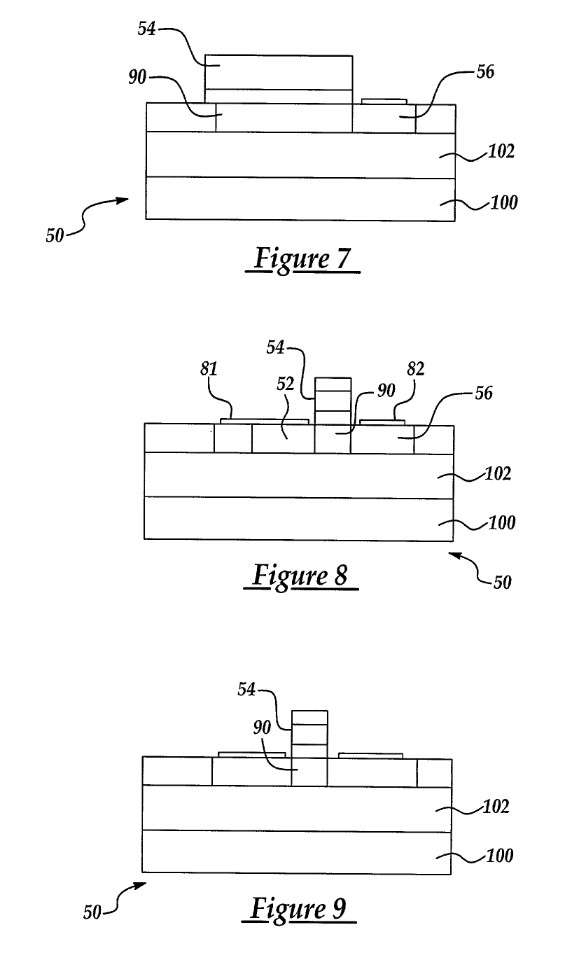

FIG. 7 illustrates a cross section AA of a body-tied-to-source SOI MOS device, in accordance with preferred or alternative embodiments of the present invention. FIGS. 7 to 9 herein thus generally depict cross sectional views of SOI MOS device 52 illustrated in FIG. 5. Note that in FIGS. 5, 7, 8, and 9, like parts are indicated by identical reference numerals.

FIG. 8 depicts a cross section BB of a body-tied-to-source SOI MOS device, in accordance with preferred or alternative embodiments of the present invention. FIG. 9 illustrates a cross section CC of a body-tied-to-source SOI MOS device, in accordance with preferred or alternative embodiments of the present invention. Thus, SOI MOS device 50 can be formed upon a substrate 100. A buried oxide layer 102 may be formed above substrate 100, including source 52,drain 56 and gate 54. Silicide layers 81 and 82 may also be formed thereon, including a body contact and a body (i.e., P).

Based on the foregoing, it can be appreciated that a number of advantages and features can be gained through an implementation of the present invention. A P+ region is located beside the source so that the total occupied area can be reduced. The P+ region is also located away from the channel so that the P+ implant has less influence on the device behavior. Additionally, the P+ region is not located anymore close to the channel so that the prior art limitations of channel length to avoid overlaps between P+ and drain regions do not exist. This is a significant improvement over the prior art devices discussed herein.

Additional poly tees may be extended from the poly gate so that the p-body is formed under the tees and the neutral body of channel can be connected to the P+ region via this newly created p-body. Note that this p-body (i.e. body 90) is specifically illustrated in FIGS. 7 to 9. Poly tees passing through the P+ region are also configured so that the newly created p-body is ensured to reach the P+ region. Poly tees passing through the P+ region can also provide the facility to add gate contacts at the side of the source (e.g., source 52).

Gate contacts on the poly tees are also available according to the device structure of the present invention so that additional gate contacts can be added to reduce the RC distribution effect along the poly gate (e.g., gate 54) and to alleviate the load of the tunneling gate leakage current, especially in the case of ultra wide and short channel devices with thin front oxide layers thereof. Finally, more than one tee can be added, as illustrated in FIG. 6, so that the pick-up capability of body contact can be improved even for ultra wide channel devices.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered. The description as set forth is thus not intended to be exhaustive or to limit the scope of the invention. Many modifications and variations are possible in light of the above teaching without departing from scope of the following claims. It is contemplated that the use of the present invention can involve components having different characteristics. It is intended that the scope of the present invention be defined by the claims appended hereto, giving full cognizance to equivalents in all respects.

What is claimed is:

1. A method for forming an SOI semiconductor device comprising a source, drain, and a gate, said method comprising the steps of:
forming said source, said drain and said gate upon a substrate, wherein said source comprises at least one source region, said drain comprises at least one drain region, and said gate comprises at least one gate region;
forming at least one P+ body contact region located adjacent said source and away from a channel of said SOI semiconductor device;
adding at least one poly tee to said gate, such that said at least one poly tee pass through said P+ body contact region; and
wherein said P+ body contact region and said source are connected together on a surface of a silicon film utilizing a silicide, thereby forming an SOI semiconductor device thereof.

2. The method of claim 1 further comprising the step of:
forming at least one gate contact, wherein said at least on gate contact is connected to said at least one poly tee.

3. The method of claim 1 further comprising the step of:
establishing said layer of silicide upon said gate, wherein said gate comprises a gate formed from polysilicon.

4. The method of claim 1 wherein said at least one poly tee comprises a polysilicon structure.

5. The method of claim 1 further comprising the step of
adding a plurality of poly tees to said SOI semiconductor device to compensate for wide channel SOI semiconductor devices.

6. The method of claim 1 further comprising the step of:
connecting said at least one source region to at least one other source region utilizing a metal-1 layer, wherein said at least one source region is separated from said at least one other source region by said at least one poly tee, such that said at least one source region and said at least one other source region together comprise said source.

7. The method of claim 1 further comprising the step of:
connecting said at least one source region to at least one other source region utilizing a P+ to body to P+ path, wherein said at least one source region is separated from said at least one other source region by said at least one poly tee, such that said at least one source region and said at least one other source region together comprise said source.

8. The method of claim 1 wherein said at least poly tee comprises an extended poly tee formed from polysilicon.

9. The method of claim 1 further comprising the step of:
shortening at least one gate of said SOI semiconductor device implanted with varying dopants utilizing said silicide, wherein said silicide is located above said at least one gate.

10. A method for forming an SOI semiconductor device comprising a source, drain, and a gate, said method comprising the steps of:
forming said source, said drain and said gate upon a substrate, wherein said source comprises at least one source region, said drain comprises at least one drain region, and said gate comprises at least one gate region;
forming at least one P+ body contact region located adjacent said source and away from a channel of said SOI semiconductor device;
adding at least one poly tee to said gate, such that said at least one poly tee pass through said P+ body contact region;
wherein said P+ body contact region and said source are connected together on a surface of a silicon film utilizing a silicide, thereby forming an SOI semiconductor device thereof;
forming at least one gate contact, wherein said at least on gate contact is connected to said at least one poly tee; and
establishing said layer of silicide upon said gate, wherein said gate comprises a gate formed from polysilicon.

11. An SOI semiconductor device comprising a source, drain, and a gate formed upon a substrate, wherein said SOI semiconductor device comprises:
at least one P+ body contact region located adjacent said source and away from a channel of said SOI semiconductor device;
at least one poly tee connected to said gate, such that said at least one poly tee pass through said P+ body contact region;
wherein said P+ body contact region and said source are connected together on a surface of a silicon film utilizing a silicide, thereby forming an SOI semiconductor device thereof.

12. The SOI semiconductor device of claim 11 further comprising:
at least one gate contact, wherein said at least on gate contact is connected to said at least one poly tee.

13. The SOI semiconductor device wherein said layer of silicide is formed upon said gate, wherein said gate comprises a gate formed from polysilicon.

14. The SOI semiconductor device of claim 11 wherein said at least one poly tee comprises a polysilicon structure.

15. The SOI semiconductor device of claim 1 further comprising:
a plurality of poly tees integrated with said SOI semiconductor device to compensate for wide channel SOI semiconductor devices.

16. The SOI semiconductor device of claim 11 further comprising:
at least one source region of said source connected to at least one other source region utilizing a metal-1 layer, wherein said at least one source region is separated from said at least one other source region by said at least one poly tee.

17. The SOI semiconductor device of claim 11 further comprising:
at least one source region of said source connected to at least one other source region utilizing a P+ to body to P+ path, wherein said at least one source region is separated from said at least one other source region by said at least one poly tee.

18. The SOI semiconductor device of claim 11 wherein said at least poly tee comprises an extended poly tee formed from polysilicon.

19. The SOI semiconductor device of claim 11 wherein at least one gate of said SOI semiconductor device implanted with varying dopants is reducible utilizing said silicide, wherein said silicide is located above said at least one gate.

20. A SOI semiconductor device comprising a source, drain, and a gate formed upon a substrate, said SOI semiconductor device comprising:
at least one P+ body contact region located adjacent said source and away from a channel of said SOI semiconductor device;
at least one poly tee connected to said gate, such that said at least one poly tee pass through said P+ body contact region;
wherein said P+ body contact region and said source are connected together on a surface of a silicon film utilizing a silicide, thereby forming an SOI semiconductor device thereof;
at least one gate contact, wherein said at least on gate contact is connected to said at least one poly tee; and
said layer of silicide formed upon said gate, wherein said gate comprises a gate formed from polysilicon.
